(19) United States
(12) Patent Application Publication
(10) Pub. No.: US 2009/0295535 A1
(43) Pub. Date: Dec. 3, 2009

(54) DEVICE FOR ACCESS CONTROL

(75) Inventor: Reinhard Pöllabauer, Vienna (AT)

Correspondence Address: CHAPMAN AND CUTLER, 111 WEST MONROE STREET, CHICAGO, IL, 60603, US

(73) Assignee: EVVA-WERK SPEZIALERZEUGUNG VON ZYLINDER-UND SICHERHEITSSCHLOSSERN GESELLSCHAFT M.B.H & CO.KG, Vienna (AT)

(21) Appl. No.: 12/309,958

(22) PCT Filed: Jul. 20, 2007
(86) PCT No.: PCT/AT2007/000356

§ 371 Date: Feb. 4, 2009

(30) Foreign Application Priority Data
Aug. 7, 2006 (AT) A1316/2006

(51) Int. Cl. G08B 29/00; H01L 31/00

(52) U.S. Cl. 340/5.2; 136/256

(57) ABSTRACT

In a device for access control comprising an electrically actuable lock and a key (12, 16) the lock and/or the key (12, 16) have/has a power supply comprising at least one thin-film solar cell (6, 10, 11, 15, 20, 21) which is fitted or applied to an area of the key (12, 16) that is exposed to the light and/or of a part electrically connected to the lock or below an energy-transmissive area of the lock, of the key (12, 16) and/or of a part electrically connected to the lock or forms said area.

The invention relates to a device for access control, having an electrically actuable lock and a key, the lock and/or the key comprising a power supply.

Electrical or electronic locks, in particular cylinder locks, normally comprise, in addition to mechanical locking mechanisms which are mechanically lockable with conventional locks, at least one electromagnetic or motor activatable locking mechanism, which is only released following an identification check. The electronic circuit used for the identification checking mostly interacts with suitable identification media in a contactless manner or by means of contacts, wherein a checking process takes place in the electronic evaluation circuit whether the respective identification medium is authorised to lock the lock. After a successful identity check, the lock is then released.

To supply energy to such an electrical or electronic locking device, a constant energy supply for the lock, and often also the key, is normally required, and it is therefore necessary to take into account not just the cost of such a constant energy supply but also the fact that an uninterruptable power supply must be available, in order to maintain the functioning of the lock in all situations.

Electrical or electronic locks can now be supplied with energy in any desired manner. As well as the possibility of a mains connection or a back-up battery, other proposals have also become known, in which the lock or the key has a transducer for converting mechanical energy into electrical energy. Such transducers are constructed for example in the form of an electrical generator and have a magnetic circuit and an induction coil penetrated by the magnetic flux thereof, wherein the magnetic circuit or the induction coil is constructed as a movable part and the other respective part as a fixed component. Thus, due to the motion of the moveable component in the induction system, an induction voltage is induced. Such a construction ensures a self-sustaining energy supply, since the electrical energy generated can be stored in an energy accumulator and if necessary made available to the electrical circuit for the identification checking or the electrical activation of the lock, as appropriate.

Flywheel generators cannot however be used for example for stationary locks, to the extent that the flywheel cannot be directly set in motion, if external actuation devices are to be dispensed with. Flywheel generators are at best suitable for the integration of a key, since in this case the flywheel, similarly to the situation in wristwatches, is set in motion due to being continuously carried and by the mechanical vibrations generated thereby. A further disadvantage of flywheel generators is the relatively inefficient operating mode, since the flywheel bearing is subject to considerable friction losses.

From DE 102004012784 A1 an electronic lock cylinder has become known, which can be actuated by a key or a rotary knob either from both sides or one side. An evaluation unit which evaluates an electronic authorisation signal is fed by a solar cell, arranged on the surface of the knob.

From EP 428892 A2, a double locking cylinder with an electrical locking/unlocking device has become known, one cylinder side carrying an activation knob with solar cells mounted on its surface.

Finally, US 2005/0132766 A1 discloses a lock arrangement with a door fitting, driven by a motor. To supply power to the motor a solar cell is attached to the exterior of the strike plate. In this case the solar cell can be formed by a thin-film solar cell.

The present invention therefore is aimed at providing an energy transducer which can be used for example for keys or locking cylinders, wherein the current generated by the energy transducer is designed to provide a constant power supply for the electrically actuable lock or key.

To solve this problem, the device according to the invention is essentially characterized in that the power supply comprises at least one thin-film solar cell, which is applied to or fitted to an area of the key that is exposed to light and/or of a part that is electrically connected to the lock, or underneath an energy transmissive area of the lock, of the key and/or a part that is electrically connected to the lock. Thin-film solar cells are particularly suitable for fitting or applying to areas of the lock, the key and/or a part that is electrically connected to the lock, or underneath appropriate energy transmissive areas respectively, since they have a high efficiency and can be deployed anywhere where energy is present in the form of light. In contrast to conventional solar cells, which require a relatively thick and stiff substrate, thin-film solar cells can be simply applied to any surface, for example those of locks or keys, whereby flexible structures are also possible. These thin-film-solar cells can be applied directly on to appropriate areas for example by vapour deposition, or finished modules can be applied on to suitable areas or underneath energy transmissive areas.

Thin-film solar cells exist in different variations depending on the substrate and vapour-deposited materials. The available range of physical properties and the range of efficiency levels is correspondingly broad. Thin-film cells differ from the traditional solar cells primarily in their production, and are manufactured for example using vapour deposition of appropriate semiconductor materials on to the surfaces of the lock, the key and/or a part that is electrically connected to the lock. Thereby a broad field of application is guaranteed in products related to locking technology. Direct semiconductors absorb sunlight even in film thicknesses of only 10 μm. These thin-film cells are mostly applied by deposition from the gas phase directly on a substrate. This can be glass, metal sheet, plastic or another material. Possible materials of thin-film cells are amorphous silicon, micro-crystalline silicon, gallium arsenide, germanium or cadmium telluride. So-called CIS cells (copper indium diselenide or copper indium disulphide) or CIGS cells (copper indium gallium diselenide) are also known.

A CIS cell for example has a thickness of less than 5 μm, whereby due to the small thickness of the film resources are saved and at appropriate production numbers a cheaper manufacturing process is possible than with thick-film technology.

A particularly preferred construction uses a dye-sensitised solar cell. Instead of using a semiconductor material for the absorption of light, electrochemical dye-sensitised solar cells use organic dyes, e.g. the leaf dye chlorophyll. The dye cell, also known as a Grätzel cell, normally consists of two planar glass electrodes separated by a distance of typically 20 to 40 μm. The two electrodes are coated on their insides with a transparent electrically conductive layer, e.g. FTO (flourine doped tin oxide), which typically has a thickness of 0.5 μm. The two electrodes are referred to according to their function as working electrode (generating electrons) and counter electrode. On the working electrode a nanoporous layer of titanium dioxide is applied with a thickness in the region of 10 μm. On the surface thereof a monolayer of a light-sensitive dye is then adsorbed. On the counter electrode there is a catalytic layer (most commonly platinum) a few μm thick. The region between the two electrodes is filled with a redox electrolyte, e.g. a solution of iodine and potassium iodide. On exposure to light the dye is chemically excited and injects electrons into the semiconductor material Ti0₂. From there these migrate to the working electrode (cathode) and by means of an external electrical circuit to the counter electrode (anode). The dye is reduced again by the iodide, which is thereby oxidised to iodine. The resulting iodine is in turn reduced at the anode with the electron back to iodide again. An internal flux of electric current is therefore formed via the electrolyte, as well as an external electrical circuit via the moving electrons. The dye-sensitised solar cell can also make good use of diffuse light in comparison to conventional solar cells. At present an efficiency of up to 11.2% is possible.

The thin-film-solar cell can preferably be applied to a surface of an activation member for the lock, in particular a doorknob. This type of application can be made both directly on an external surface of the activation member as well as underneath an appropriately energy transmissive covering layer of the activation member. A completely integrated and compact construction is thus achieved, the thin film-solar cell being directly electrically connected to a current accumulator situated in the activation member or a cylinder that is electrically connected to the activation member, so that the lock is equipped with a completely self-sustaining power supply.

Another preferred construction is characterized in that the thin-film solar cell is fitted or applied underneath an energy transmissive area of a door fitting that is electrically connected to the lock or forms the surface thereof. The door fitting in this arrangement offers space for application of the thin-film-solar cells over an as large a surface area as possible, so that a correspondingly large amount of current can be generated. The thin-film solar cells here can be applied to the external and/or the inner fitting, with application on the inner fitting providing effective protection against sabotage or acts of vandalism. The solar cell can form the surface of the fitting or be arranged underneath an energy transmissive covering of the fitting, the latter possibility guaranteeing a particularly sabotage and vandal-proof placement.

The thin-film solar cell does not necessarily need to be applied to the lock itself, but can also be arranged on a separate part electrically connected to the lock, and in this case it is preferably provided that the thin-film solar cell is applied on a surface of a reader unit for an electronic key that is electrically connected to the lock.

Finally it is also conceivable to apply the thin-film solar cell to a front face of a lock cylinder, which leads to a particularly compact type of construction.

Another preferred construction is one in which the thin-film solar cell is arranged on an electronic key and/or underneath an energy transmissive area of the key. In this arrangement the current supplied by the thin-film solar cell can be used both to supply the key electronics and also to supply the lock. In the latter case the energy stored in the key can be transmitted from the key to the lock electronics when electrical contact is made to the lock during the locking process.

The arrangement of the thin-film-solar cell according to the invention allows a constant supply of power, depending on the current consumption of the connected electronics. To increase the failure protection however it is preferably provided that the power supply has a chargeable current accumulator fed by the solar cell.

The invention is explained below in further detail with the aid of exemplary embodiments schematically illustrated in the drawings.

In these,

FIG. 1 shows a fitting with a polymer solar cell,

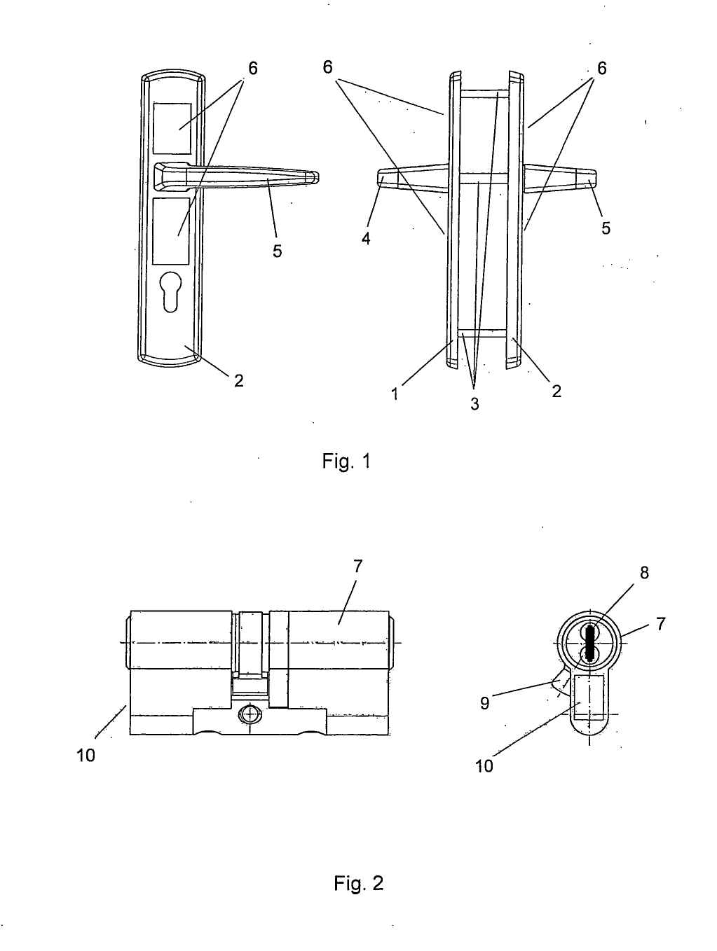

FIG. 2 a lock cylinder with a silicon solar cell applied to its front face,

FIG. 3 an electronic key with a dye-sensitised solar cell,

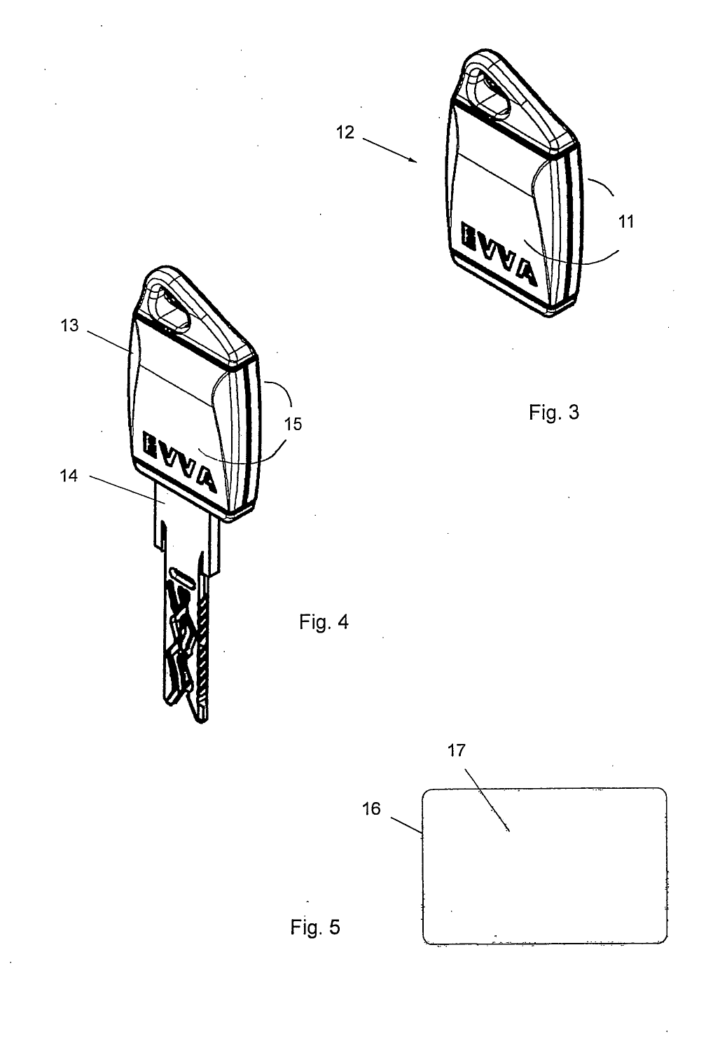

FIG. 4 a key with an organic solar cell,

FIG. 5 an electronic key in the shape of a card with a flexible thin-film solar cell,

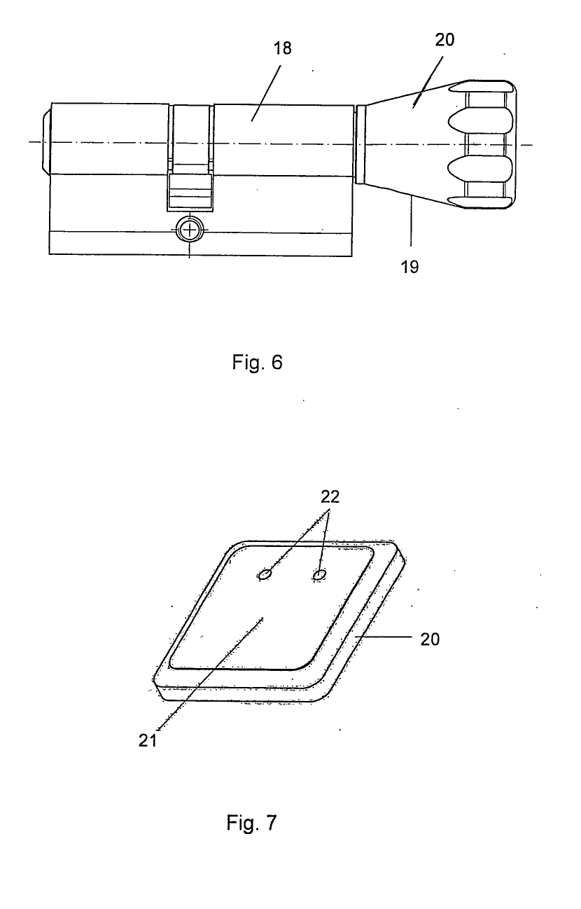

FIG. 6 a door knob with an organic solar cell and

FIG. 7 a wall reader with plastic polymer solar cells.

In FIG. 1 an external fitting is labelled with 1 and an inner fitting is labelled with 2 which are held together by means of connecting bolts 3. The door handles for activating the lock member are labelled with 4 and 5. On the external and/or the inner fitting 1 and 2 respectively polymer solar cells 6 are arranged, wherein the solar cells 6 can be for example vapour-deposited on to the surface of the fitting. The solar cell can be fitted on the fitting surface, or also form the fitting surface itself. On the other hand the solar cell can also be arranged underneath an energy transmissive surface, for example a transparent surface of the fitting.

In FIG. 2 a lock cylinder 7 is shown with a key channel 8 and an activation member 9. The solar cell 10 here is fitted on the front face of the cylinder, wherein the fitting can be on the inside and/or the outside. The solar cell 10 here is preferably in the form of a thin-film silicon solar cell.

In the construction according to FIG. 3 a solar cell 11 is arranged in an electronic key 12, wherein the electronic key 12 in this case is in the form of a carrier for an electronic code. The solar cell 11 in this arrangement can be in the form of a dye-sensitised solar cell and be arranged for example underneath the energy transmissive housing of the electronic key 12. The solar cell 11 can be fitted on the front and/or on the rear of the electronic key 12.

The construction according to FIG. 4 is essentially equivalent to the construction according to FIG. 3, wherein in addition to the part 13 of the key containing the electronic key a mechanically acting key 14 is provided. The solar cell here is again arranged in the plastic handle part 13, wherein here again a transparent plastic window can be provided, under which the solar cell 15, in the present case for example an organic solar cell, can be arranged.

In FIG. 5 an electronic key 16 is shown, which is embodied in the form of a cheque card. The cheque card 16 is constructed for example in the form of a transponder card and contains an electronic key. In a cheque card of this kind it is particularly important that the built-in solar cell has a flexible construction, so that it is not destroyed if the plastic card is bent. The schematically indicated solar cell can for example be in the form of a flexible organic solar cell and be mounted on the surface of the cheque card 16.

In FIG. 6 a lock cylinder 18 is illustrated with a knob 19 fitted to it, a solar cell 20 being integrated into the knob 19. This integration can be done for example in such a manner that a flexible organic solar cell is arranged underneath a transparent plastic material of the knob. A flexible thin-film solar cell in this arrangement can follow the cylindrical form of the knob very well.

In FIG. 7 finally, a wall reader is shown that can be electrically connected to a lock. The wall reader 20 can for example have the form of a reading device for a transponder key and has a surface, on to which for example plastic polymer solar cells 21 can be applied. The energy supplied by the solar cell 21 here serves to supply power to the reader electronics, wherein display elements 22 can optionally be provided, which are formed for example by LEDs and also fed with power from the solar cell 21. The power supplied by the solar cell 21 can also be made available to the electrical lock to which the reader unit 20 is electrically connected.

1-11. (canceled)

12. Device for access control, comprising:
an electrically actuable lock; and
a key, wherein
one or more of said lock and said key comprise a power supply, and
the power supply comprises at least one thin-film solar cell applied to or fitted to one or more of
an area of the key that is exposed to light,
an area of a part that is electrically connected to the lock, and
a portion that forms, or is underneath, an energy transmissive area of at least one of the lock, the key, and the part that is electrically connected to the lock.

13. Device according to claim 12, wherein the thin-film solar cell is an organic solar cell.

14. Device according to claim 12, wherein the thin-film solar cell is a dye-sensitized solar cell.

15. Device according to claim 12, wherein the thin-film solar cell is a polymer solar cell or a polymer plastic solar cell.

16. Device according to claim 12, wherein the thin-film solar cell comprises at least one of:
amorphous silicon, micro-crystalline silicon, gallium arsenide, germanium, cadmium telluride, copper indium (gallium) sulphur compounds, and copper indium diselenide.

17. Device according to claim 12, wherein the thin-film solar cell is applied to or fitted on to a surface of, or underneath an energy transmissive area of, a doorknob of the lock, or forms said doorknob surface.

18. Device according to claim 12, wherein the thin-film solar cell is applied to or fitted underneath an energy transmissive surface of a door fitting of the lock, or forms a surface of said door fitting.

19. Device according to claim 12, wherein the thin-film solar cell is applied to or fitted on to a surface of, or underneath an energy transmissive area of, a reader unit for an electronic key which is electrically connected to the lock, or forms said surface of the reader unit.

20. Device according to claim 12, wherein the thin-film solar cell is applied to or fitted on to a front face of a cylinder of the lock, or underneath an energy transmissive surface of the lock cylinder, or forms said surface of the lock cylinder.

21. Device according to claim 12, wherein the thin-film solar cell is arranged underneath an energy transmissive area of the key.

22. Device according to claim 12, wherein the power supply further comprises a chargeable current accumulator which is fed by the solar cell.

23. Device according to claim 17, wherein the thin-film solar cell is an organic solar cell.

24. Device according to claim 17, wherein the thin-film solar cell is a dye-sensitized solar cell.

25. Device according to claim 17, wherein the thin-film solar cell is a polymer solar cell or a polymer plastic solar cell.

26. Device according to claim 18, wherein the thin-film solar cell is an organic solar cell.

27. Device according to claim 18, wherein the thin-film solar cell is a dye-sensitized solar cell.

28. Device according to claim 18, wherein the thin-film solar cell is a polymer solar cell or a polymer plastic solar cell.

29. Device according to claim 19, wherein the thin-film solar cell is an organic solar cell.

30. Device according to claim 19, wherein the thin-film solar cell is a dye-sensitized solar cell.

31. Device according to claim 19, wherein the thin-film solar cell is a polymer solar cell or a polymer plastic solar cell.
